(19) United States
(12) Patent Application Publication
(10) Pub. No.: US 2024/0057435 A1
(43) Pub. Date: Feb. 15, 2024

(54) DISPLAY DEVICE

(71) Applicant: Samsung Display Co., LTD., Yongin-si (KR)

(72) Inventors: WOONGSIK KIM, Yongin-si (KR); GUNSHIK KIM, Yongin-si (KR); SIKWANG KIM, Yongin-si (KR); JIN-SU BYUN, Yongin-si (KR)

(21) Appl. No.: 18/193,154

(22) Filed: Mar. 30, 2023

(30) Foreign Application Priority Data
Aug. 9, 2022 (KR) 10-2022-0099126

(51) Int. Cl. H10K 59/38; H10K 59/80

(52) U.S. Cl. CPC H10K 59/38; H10K 59/877; H10K 59/12

(57) ABSTRACT

A display device includes a substrate, a color conversion pattern on the substrate and including scattering particles, a first pixel electrode under the color conversion pattern and that extends to surround a side surface of the color conversion pattern, a second pixel electrode on the color conversion pattern and connected to the first pixel electrode, and a light emitting layer on the second pixel electrode.

### CROSS-REFERENCE TO RELATED APPLICATION

This application claims priority to and the benefit of Korean Patent Application No. 10-2022-0099126, filed on Aug. 9, 2022, in the Korean Intellectual Property Office (KIPO), the entire content of which is incorporated by reference herein.

### BACKGROUND

### 1. Field

Embodiments of the present disclosure relate to a display device. For example, embodiments relate to a display device providing visual information.

### 2. Description of the Related Art

A display device includes a light emitting layer and a plurality of color conversion patterns. Light is emitted from the light emitting layer, and the color conversion patterns convert a color of the light. Accordingly, the color conversion patterns may emit (or transmit) light having a color different from a color of incident light.

The color conversion patterns may include quantum dots, and may be classified into red color conversion patterns, green color conversion patterns, and scattering patterns (or blue color conversion patterns). The red color conversion pattern implements a red pixel, the green color conversion pattern implements a green pixel, and the scattering pattern implements a blue pixel.

### SUMMARY

Embodiments of the present disclosure provide a display device having improved display quality.

A display device according to an embodiment of the present disclosure may include a substrate, a color conversion pattern on the substrate and including light scattering particles, a first pixel electrode under the color conversion pattern and that extends to surround a side surface of the color conversion pattern, a second pixel electrode on the color conversion pattern and connected to the first pixel electrode, and a light emitting layer on the second pixel electrode.

In an embodiment, the first pixel electrode may include a first portion under the color conversion pattern and a second portion that extends from a side surface of the first portion to surround a side surface of the color conversion pattern, and the second pixel electrode may directly come into contact with the second portion of the first pixel electrode.

In an embodiment, the display device may further include a via insulating layer on the substrate and that defines an opening overlapping the first pixel electrode. The first pixel electrode and the color conversion pattern may be in the opening.

In an embodiment, the second pixel electrode may be on the via insulating layer.

In an embodiment, the display device may further include a pixel defining layer on the via insulating layer to expose at least a portion of the second pixel electrode.

In an embodiment, the display device may further include a via insulating layer on the substrate and a first pixel defining layer on the via insulating layer and defining an opening that exposes a portion of an upper surface of the via insulating layer. The first pixel electrode and the color conversion pattern may be in the opening.

In an embodiment, the second pixel electrode may be on the first pixel defining layer.

In an embodiment, the display device may further include a second pixel defining layer on the first pixel defining layer to expose at least a portion of the second pixel electrode.

In an embodiment, the first pixel electrode may have a multilayer structure, and the second pixel electrode may have a single-layer structure.

In an embodiment, the first pixel electrode may include ITO/Ag/ITO, and the second pixel electrode may include ITO.

In an embodiment, an upper surface of the color conversion pattern may have a concave cross-sectional shape or a convex cross-sectional shape.

In an embodiment, the second pixel electrode may be along a profile of the upper surface of the color conversion pattern.

In an embodiment, the display device may further include a color filter layer on the light emitting layer and including a first color filter, a second color filter, and a third color filter.

A display device according to an embodiment of the present disclosure may include a substrate, a first pixel electrode on the substrate and having a multilayer structure, a via insulating layer on the substrate and that defines an opening that exposes a portion of an upper surface of the first pixel electrode, a color conversion pattern in the opening and including scattering particles, a second pixel electrode on the via insulating layer, connected to the first pixel electrode via a contact hole formed through the via insulating layer, and having a single-layer structure, and a light emitting layer on the second pixel electrode.

In an embodiment, the first pixel electrode may include ITO/Ag/ITO, and the second pixel electrode may include ITO.

In an embodiment, the display device may further include a pixel defining layer on the via insulating layer to expose at least a portion of the second pixel electrode.

In an embodiment, the via insulating layer may include a high refractive index material.

In an embodiment, the via insulating layer may have a refractive index of 1.6 or more.

In an embodiment, an upper surface of the color conversion pattern may have a concave cross-sectional shape or a convex cross-sectional shape.

In an embodiment, the second pixel electrode may be along a profile of the upper surface of the color conversion pattern.

In the display device according to embodiments of the present disclosure, because the color conversion pattern is between the first pixel electrode and the second pixel electrode, a distance between the light emitting layer and the color conversion pattern may be shortened. Accordingly, a scattering reflection phenomenon caused by the quantum dots and scattering particles included in the color conversion pattern and the scattering reflection phenomenon due to microscopic light emission of the quantum dots by an external light source can be improved.

In addition, because a separate space for the color conversion pattern is not required, the manufacturing process of the display device can be simplified. Accordingly, display quality and productivity of the display device can be improved.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a plan view illustrating a display device according to an embodiment of the present disclosure.

FIG. 2 is a cross-sectional view taken along line I-I′ of FIG. 1.

FIG. 3 is an enlarged cross-sectional view of an area A in FIG. 2.

FIGS. 4 to 12 are cross-sectional views illustrating a manufacturing method of the display device shown in FIG. 1

FIG. 13 is a cross-sectional view illustrating a display device according to another embodiment of the present disclosure.

FIG. 14 is a cross-sectional view illustrating a display device according to still another embodiment of the present disclosure.

FIG. 15 is a cross-sectional view illustrating a display device according to still another embodiment of the present disclosure.

### DETAILED DESCRIPTION

Hereinafter, embodiments of the present disclosure will be described in more detail with reference to the accompanying drawings. The same reference numerals are used for the same components in the drawings, and redundant descriptions of the same components may not be repeated.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. A reference number labeling a singular form of an element within the drawing figures may be used to reference a plurality of the singular element within the text of specification.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

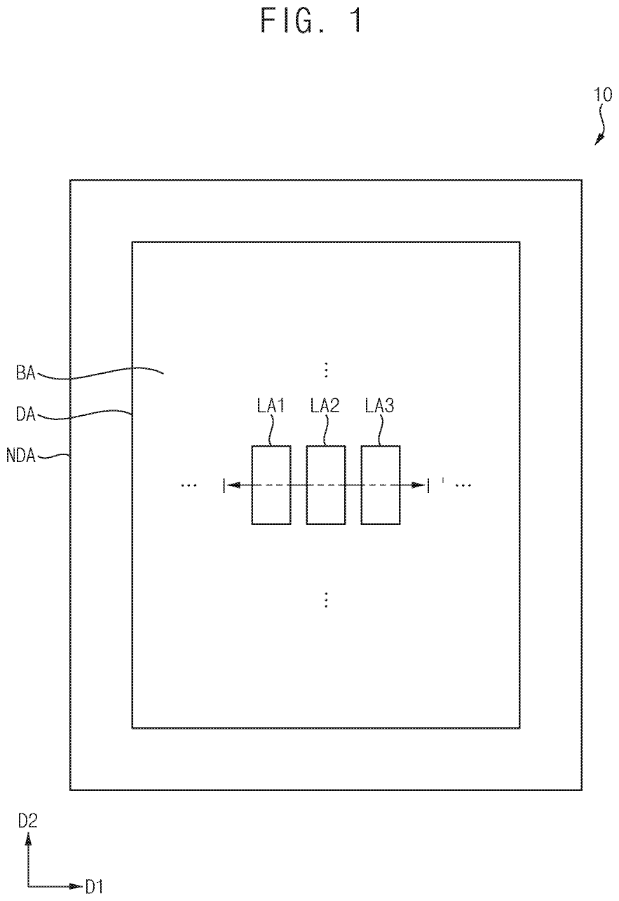

FIG. 1 is a plan view illustrating a display device according to an embodiment of the present disclosure.

Referring to FIG. 1, a display device 10 according to an embodiment of the present disclosure may include a display area DA and a non-display area NDA. The display area DA may be defined as an area that displays an image. The non-display area NDA may be defined as an area that does not display an image. The non-display area NDA may be located around the display area DA. For example, the non-display area NDA may entirely surround the display area DA (e.g., may entirely surround the display area DA in a plane, such as a horizontal plane).

The display area DA may include a plurality of light emitting areas and a light blocking area BA. The plurality of light emitting areas may include a first light emitting area LA1, a second light emitting area LA2, and a third light emitting area LA3.

Each of the first, second, and third light emitting areas LA1, LA2, and LA3 may be an area through which light emitted from the light emitting element is emitted to the outside of the display device 10. For example, the first light emitting area LA1 may emit light of a first color, the second light emitting area LA2 may emit light of a second color, and the third light emitting area LA3 may emit light of a third color. In an embodiment, the first light may be red light, the second light may be green light, and the third light may be blue light. However, the present disclosure is not limited thereto.

The first, second, and third light emitting areas LA1, LA2, and LA3 may emit four or more lights. For example, the first, second, and third light emitting areas LA1, LA2, and LA3 may be combined to further emit at least one of yellow, cyan, or magenta lights in addition to red, green, and blue lights. In addition, the first, second, and third light emitting areas LA1, LA2, and LA3 may be combined to further emit white light.

When viewed in a plan view, each of the first, second, and third light emitting areas LA1, LA2, and LA3 may be repeatedly arranged along a row direction and a column direction. For example, each of the first, second, and third light emitting areas LA1, LA2, and LA3 may be repeatedly arranged along a first direction D1 and a second direction D2 orthogonal to the first direction D1.

The light blocking area BA may be positioned between the first, second, and third light emitting areas LA1, LA2, and LA3. For example, when viewed in a plan view, the light blocking area BA may surround the first, second, and third light emitting areas LA1, LA2, and LA3. The light blocking area BA may not emit light.

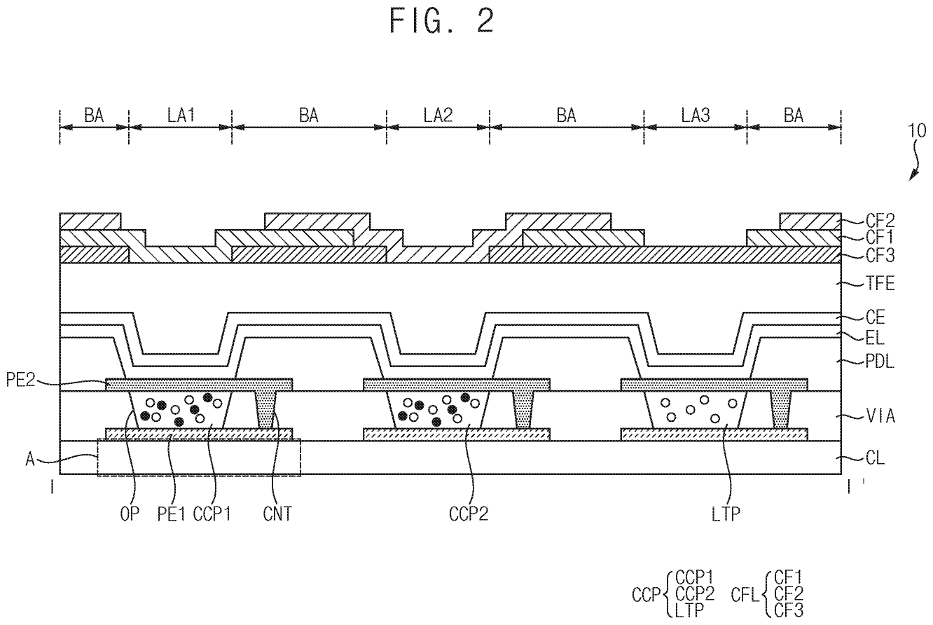

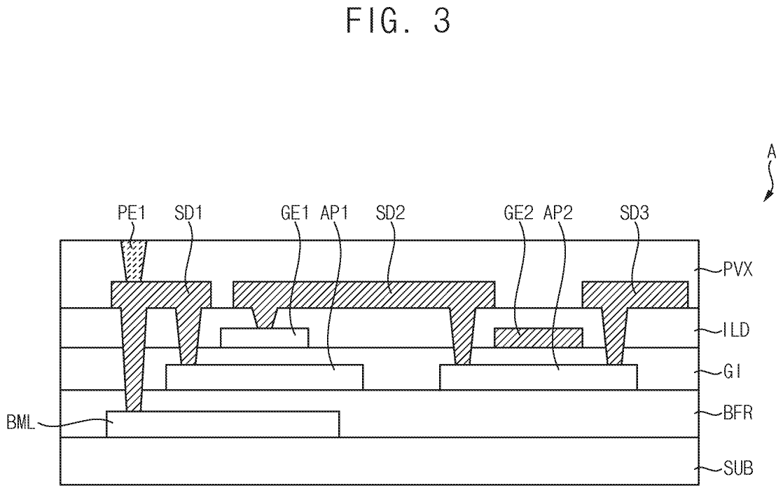

FIG. 2 is a cross-sectional view taken along line I-I′ of FIG. 1, and FIG. 3 is an enlarged cross-sectional view of an area A in FIG. 2. For example, FIGS. 2 and 3 are cross-sectional views illustrating an example of the display area DA of the display device 10 of FIG. 1.

For example, FIG. 3 is an enlarged cross-sectional view of a circuit layer CL in the first light emitting area LA1. Although the cross-sectional structure of the circuit layer CL in the second and third light emitting areas LA2 and LA3 is not shown in FIG. 3, the cross-sectional structure of the circuit layer in the second and third light emitting areas LA2 and LA3 may be substantially the same as the cross-sectional structure of the circuit layer CL in the first light emitting area LA1.

Referring to FIGS. 2 and 3, the display device 10 according to an embodiment of the present disclosure may include a circuit layer CL, a first pixel electrode PE1, a via insulating layer VIA, a color conversion pattern CCP, a second pixel electrode PE2, a pixel defining layer PDL, a light emitting layer EL, a common electrode CE, a thin film encapsulation layer TFE, and a color filter layer CFL.

The circuit layer CL may include a substrate SUB, a lower pattern BML, a buffer layer BFR, a first active pattern AP1, a second active pattern AP2, a gate insulating layer GI, a first gate electrode GE1, a second gate electrode GE2, an interlayer insulating layer ILD, a first electrode SD1, a second electrode SD2, a third electrode SD3, and a passivation layer PVX.

The substrate SUB may include a transparent material or an opaque material. Examples of materials that may be used as the substrate SUB may include glass, quartz, plastic, and the like. These materials may be used alone or in combination with each other.

The lower pattern BML may be on the substrate SUB. In an embodiment, the lower pattern BML may include a conductive material (e.g., an electrically conductive material). Examples of conductive materials that may be used as the lower pattern BML may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), and the like. These materials may be used alone or in combination with each other.

The buffer layer BFR may be on the substrate SUB to cover the lower pattern BML. In an embodiment, the buffer layer BFR may include an inorganic material. Examples of inorganic materials that may be used as the buffer layer BFR may include silicon oxide, silicon nitride, silicon oxynitride, and the like. These materials may be used alone or in combination with each other. The buffer layer BFR may prevent or reduce penetration of metal atoms and/or impurities into the first active pattern AP1 and second active pattern AP2. In addition, the buffer layer BFR may control a heat supply rate during a crystallization process for forming the first active pattern AP1 and the second active pattern AP2.

The first active pattern AP1 and the second active pattern AP2 may be on the buffer layer BFR. In an embodiment, each of the first active pattern AP1 and the second active pattern AP2 may include a silicon semiconductor material or an oxide semiconductor material. Examples of silicon semiconductor materials that may be used for each of the first active pattern AP1 and the second active pattern AP2 may include amorphous silicon, polycrystalline silicon, and the like. Examples of oxide semiconductor materials that may be used for each of the first active pattern AP1 and the second active pattern AP2 may include indium gallium zinc oxide (IGZO), indium tin zinc oxide (ITZO), and the like. These materials may be used alone or in combination with each other. Each of the first active pattern AP1 and the second active pattern AP2 may have a source area, a drain area, and a channel area positioned between the source area and the drain area.

The gate insulating layer GI may be on the buffer layer BFR to cover the first active pattern AP1 and the second active pattern AP2. In an embodiment, the gate insulating layer GI may include an inorganic insulating material (e.g., an inorganic electrically insulating material). Examples of inorganic insulating materials that may be used as the gate insulating layer GI may include silicon oxide, silicon nitride, silicon oxynitride, and the like. These materials may be used alone or in combination with each other.

The first gate electrode GE1 and the second gate electrode GE2 may be on the gate insulating layer GI. The first gate electrode GE1 may overlap the channel area of the first active pattern AP1. The second gate electrode GE2 may overlap the channel area of the second active pattern AP2. In an embodiment, each of the first gate electrode GE1 and the second gate electrode GE2 may include a conductive material (e.g., an electrically conductive material). Examples of conductive materials that may be used for each of the first gate electrode GE1 and the second gate electrode GE2 may include aluminum, platinum, palladium, silver, magnesium, gold, nickel, neodymium, iridium, chromium, lithium, calcium, molybdenum, titanium, tungsten, copper, and the like. These materials may be used alone or in combination with each other.

The interlayer insulating layer ILD may be on the gate insulating layer GI to cover the first gate electrode GE1 and the second gate electrode GE2. In an embodiment, the interlayer insulating layer ILD may include an inorganic insulating material. Examples of inorganic insulating materials that may be used as the interlayer insulating layer ILD may include silicon oxide, silicon nitride, silicon oxynitride, and the like. These materials may be used alone or in combination with each other.

The first electrode SD1, the second electrode SD2, and the third electrode SD3 may be on the interlayer insulating layer ILD. Each of the first, second, and third electrodes SD1, SD2, and SD3 may include a conductive material (e.g., an electrically conductive material). Examples of conductive materials that may be used for each of the first, second, and third electrodes SD1, SD2, and SD3 may include aluminum, platinum, palladium, silver, magnesium, gold, nickel, neodymium, iridium, chromium, lithium, calcium, molybdenum, titanium, tungsten, copper, and the like. These materials may be used alone or in combination with each other.

The first electrode SD1 may come into contact (e.g., physical contact) with the lower pattern BML through a contact hole formed in the buffer layer BFR, the gate insulating layer GI, and the interlayer insulating layer ILD. In addition, the first electrode SD1 may come into contact (e.g., physical contact) with the drain area of the first active pattern AP1 through a contact hole formed in the gate insulating layer GI and the interlayer insulating layer ILD. The second electrode SD2 may come into contact (e.g., physical contact) with the first gate electrode GE1 through a contact hole formed in the interlayer insulating layer ILD. In addition, the second electrode SD2 may come into contact (e.g., physical contact) with the drain area of the second active pattern AP2 through a contact hole formed in the gate insulating layer GI and the interlayer insulating layer ILD. The third electrode SD3 may come into contact (e.g., physical contact) with the source area of the first active pattern AP1 through a contact hole formed in the gate insulating layer GI and the interlayer insulating layer ILD.

The passivation layer PVX may be on the interlayer insulating layer ILD to cover the first electrode SD1, the second electrode SD2, and the third electrode SD3. In an embodiment, the first pixel electrode PE1 may come into contact (e.g., physical contact) with the first electrode SD1 through a contact hole formed in the passivation layer PVX. The passivation layer PVX may include an inorganic material and/or an organic material. Examples of inorganic materials that may be used as the passivation layer PVX may include silicon oxide, silicon nitride, silicon oxynitride, and the like. Examples of organic materials that may be used as the passivation layer PVX may include photoresist, polyacrylic resin, polyimide resin, acrylic resin, and the like. These materials may be used alone or in combination with each other.

The first pixel electrode PE1 may be on the circuit layer CL. The first pixel electrode PE1 may be in each of the first, second, and third light emitting areas LA1, LA2, and LA3.

The first pixel electrode PE1 may include a conductive material (e.g., electrically conductive material). Examples of conductive materials that may be used as the first pixel electrode PE1 may include aluminum, platinum, palladium, silver, magnesium, gold, nickel, neodymium, iridium, chromium, lithium, calcium, molybdenum, titanium, tungsten, copper, indium tin oxide (ITO), indium zinc oxide (IZO), and the like. These materials may be used alone or in combination with each other.

In an embodiment, the first pixel electrode PE1 may have a multilayer structure. For example, the first pixel electrode PE1 may include ITO/Ag/ITO.

The via insulating layer VIA may be on the circuit layer CL. In an embodiment, an opening OP that exposes at least a portion of an upper surface of the first pixel electrode PE1 may be defined in the via insulating layer VIA. The opening OP may overlap each of the first, second, and third light emitting areas LA1, LA2, and LA3. The via insulating layer VIA may include an organic insulating material. Examples of organic insulating materials that may be used as the via insulating layer VIA may include photoresist, polyacrylic resin, polyimide resin, acrylic resin, and the like. These materials may be used alone or in combination with each other.

In an embodiment, the via insulating layer VIA may include a high refractive index material. For example, the refractive index of the via insulating layer VIA may be about 1.6 or more (e.g., a refractive index of 1.6 or more at a wavelength of 589 nm). In another embodiment, the via insulating layer VIA may include an organic material including a black pigment and/or a black dye.

The color conversion pattern CCP may be on the first pixel electrode PE1. For example, the color conversion pattern CCP may be in the opening OP of the via insulating layer VIA.

In an embodiment, the color conversion pattern CCP may include a first color conversion pattern CCP1, a second color conversion pattern CCP2, and a light transmission pattern LTP. The first color conversion pattern CCP1 may be in the first light emitting area LA1, the second color conversion pattern CCP2 may be in the second light emitting area LA2, and the light transmission pattern LTP may be in the third light emitting area LA3. The first and second color conversion patterns CCP1 and CCP2 may convert light emitted from the light emitting layer EL into light having a set or specific wavelength.

The first color conversion pattern CCP1 may include first quantum dots excited by light emitted from the light emitting layer EL to emit light of a first color. In addition, the first color conversion pattern CCP1 may further include first scattering particles (e.g., first light scattering particles) and a first photosensitive polymer in which the first scattering particles are dispersed. In an embodiment, the first color conversion pattern CCP1 may convert the light emitted from the light emitting layer EL into the light of the first color. For example, as the light emitted from the light emitting layer EL passes through the first color conversion pattern CCP1, red light may be emitted from the first light emitting area LA1, but the present disclosure is not limited thereto.

The second color conversion pattern CCP2 may include second quantum dots excited by the light emitted from the light emitting layer EL to emit light of a second color. In addition, the second color conversion pattern CCP2 may further include second scattering particles (e.g., second light scattering particles) and a second photosensitive polymer in which the second scattering particles are dispersed. In an embodiment, the second color conversion pattern CCP2 may convert the light emitted from the light emitting layer EL into the light of the second color. For example, as the light emitted from the light emitting layer EL passes through the second color conversion pattern CCP2, green light may be emitted from the second light emitting area LA2, but the present disclosure is not limited thereto.

The light transmission pattern LTP may include third scattering particles (e.g., third light scattering particles) and a third photosensitive polymer in which the third scattering particles are dispersed. In an embodiment, the light transmission pattern LTP may transmit the light emitted from the light emitting layer EL. For example, as the light emitted from the light emitting layer EL passes through the light transmission pattern LTP, blue light may be emitted from the third light emitting area LA3, but the present disclosure is not limited thereto.

For example, the first, second, and third scattering particles may scatter and emit the light emitted from the light emitting layer EL. In addition, the first, second, and third scattering particles may include the same material. Each of the first, second, and third photosensitive polymers may include an organic material having a light transmitting property such as a silicone resin and/or an epoxy resin.

The second pixel electrode PE2 may be on the via insulating layer VIA and the color conversion pattern CCP. The second pixel electrode PE2 may be in each of the first, second, and third light emitting areas LA1, LA2, and LA3.

The second pixel electrode PE2 may include a conductive material (e.g., an electrically conductive material). Examples of conductive materials that may be used as the second pixel electrode PE2 may include aluminum, platinum, palladium, silver, magnesium, gold, nickel, neodymium, iridium, chromium, lithium, calcium, molybdenum, titanium, tungsten, copper, indium tin oxide, indium zinc oxide, and the like. These materials may be used alone or in combination with each other.

In an embodiment, the second pixel electrode PE2 may have a single-layer structure. For example, the second pixel electrode PE2 may include ITO. The second pixel electrode PE2 may be connected to the first pixel electrode PE1 through a contact hole CNT formed in the via insulating layer VIA.

The pixel defining layer PDL may be on the via insulating layer VIA. In an embodiment, an opening that exposes at least a portion of an upper surface of the second pixel electrode PE2 may be defined in the pixel defining layer PDL. The opening may overlap each of the first, second, and third light emitting areas LA1, LA2, and LA3. The pixel defining layer PDL may include an organic insulating material (e.g., an organic electrically insulating material). Examples of organic insulating materials that may be used as the pixel defining layer PDL may include photoresist, polyacrylic resin, polyimide resin, acrylic resin, and the like. These materials may be used alone or in combination with each other.

The light emitting layer EL may be on the pixel defining layer PDL. The light emitting layer EL may be entirely formed in the first, second, and third light emitting areas LA1, LA2, and LA3 and the light blocking area BA. The light emitting layer EL may be formed of an organic material to emit light of a set or predetermined color. For example, the light emitting layer EL may emit blue light, but the present disclosure is not limited thereto.

The common electrode CE may be on the light emitting layer EL. The common electrode CE may be entirely formed in the first, second, and third light emitting areas LA1, LA2, and LA3 and the light blocking area BA. The common electrode CE may include metal. Examples of metals that may be used as the common electrode CE may include lithium, calcium, aluminum, silver, magnesium, and the like. These materials may be used alone or in combination with each other.

The thin film encapsulation layer TFE may be on the common electrode CE. The thin film encapsulation layer TFE may include an insulating material (e.g., an electrically insulating material). For example, the thin film encapsulation layer TFE may have a structure in which inorganic layers and organic layers are alternately stacked. The thin film encapsulation layer TFE may prevent or reduce penetration of foreign materials into the light emitting layer EL.

The color filter layer CFL may be on the thin film encapsulation layer TFE. The color filter layer CFL may include a first color filter CF1, a second color filter CF2, and a third color filter CF3. The first, second, and third color filters CF1, CF2, and CF3 may selectively transmit light having a set or specific wavelength.

The first color filter CF1 may partially overlap the first color conversion pattern CCP1, the second color filter CF2 may partially overlap the second color conversion pattern CCP2, and the third color filter CF3 may partially overlap the light transmission pattern LTP.

For example, the first color filter CF1 may transmit red light and block (e.g., reduce transmission of) lights having colors different from the red light. The second color filter CF2 may transmit green light and block (e.g., reduce transmission of) lights having colors different from the green light. The third color filter CF3 may transmit blue light and block (e.g., reduce transmission of) lights having colors different from the blue light. However, the present disclosure is not limited thereto.

A separate upper space for forming the color conversion pattern may be on the thin film encapsulation layer. In this case, a scattering reflection phenomenon (e.g., a light scattering reflection phenomenon) caused by quantum dots and scattering particles (e.g., light scattering particles) included in the color conversion pattern may increase, so that the display quality of the display device may deteriorate (e.g., may be reduced).

In the display device 10 according to an embodiment of the present disclosure, because the color conversion pattern CCP is between the first pixel electrode PE1 and the second pixel electrode PE2, the distance between the light emitting layer EL and the color conversion pattern CCP may be shortened. Accordingly, the scattering reflection phenomenon caused by the quantum dots and scattering particles included in the color conversion pattern CCP and the scattering reflection phenomenon due to the microscopic light emission of the quantum dots by an external light source may be improved.

In addition, because a separate space for the color conversion pattern CCP is not required, the manufacturing process of the display device 10 may be simplified. Accordingly, the display quality and productivity of the display device 10 may be improved.

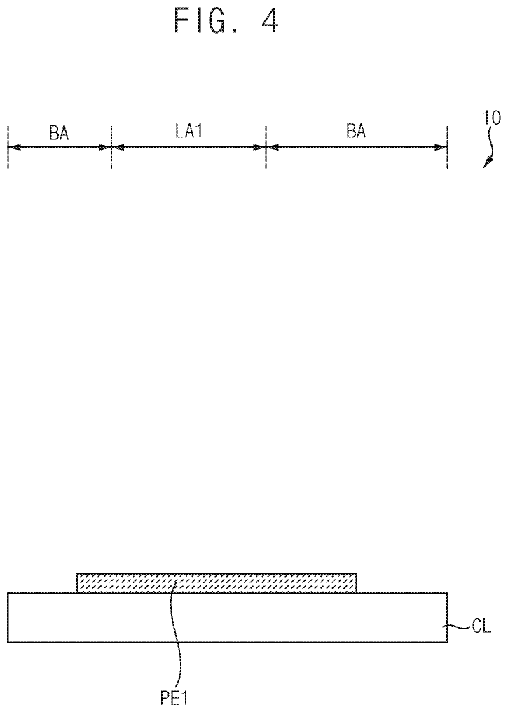

FIGS. 4 to 12 are cross-sectional views illustrating an embodiment of a manufacturing method of the display device shown in FIG. 1. For example, FIGS. 4 to 12 are cross-sectional views illustrating a manufacturing method of the display device 10 in the first light emitting area LA1. Although a cross-sectional structure illustrating a manufacturing method of the display device 10 in the second light emitting area LA2 and the third light emitting area LA3 is not shown in FIGS. 4 to 12, the manufacturing method of the display device 10 in the second light emitting area LA2 and the third light emitting area LA3 may be substantially the same as the manufacturing method of the display device 10 in the first light emitting area LA1.

Referring to FIG. 4, the first pixel electrode PE1 may be formed on the circuit layer CL. The first pixel electrode PE1 may overlap the first emitting area LA1. In an embodiment, the first pixel electrode PE1 may have a multilayer structure. For example, the first pixel electrode PE1 may include ITO/Ag/ITO.

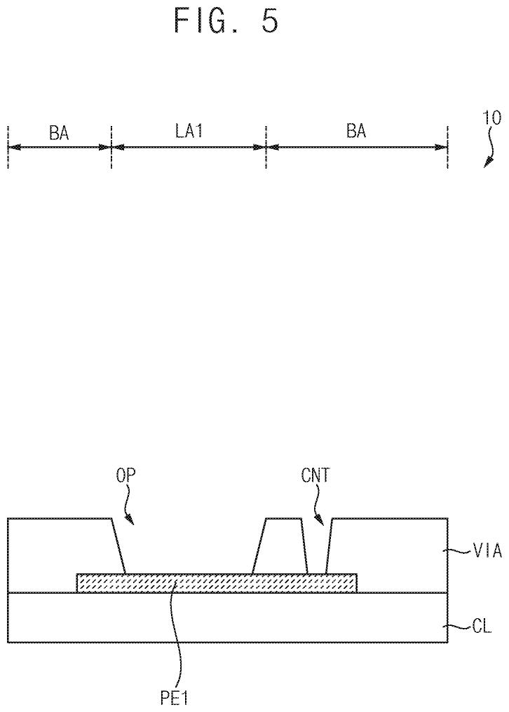

Referring to FIG. 5, the via insulating layer VIA may be formed on the circuit layer CL. In an embodiment, the opening OP that exposes at least a portion of an upper surface of the first pixel electrode PE1 may be formed in the via insulating layer VIA. The opening OP may overlap the first emitting area LA1. In addition, the contact hole CNT that exposes at least a portion of an upper surface of the first pixel electrode PE1 may be formed in the via insulating layer VIA.

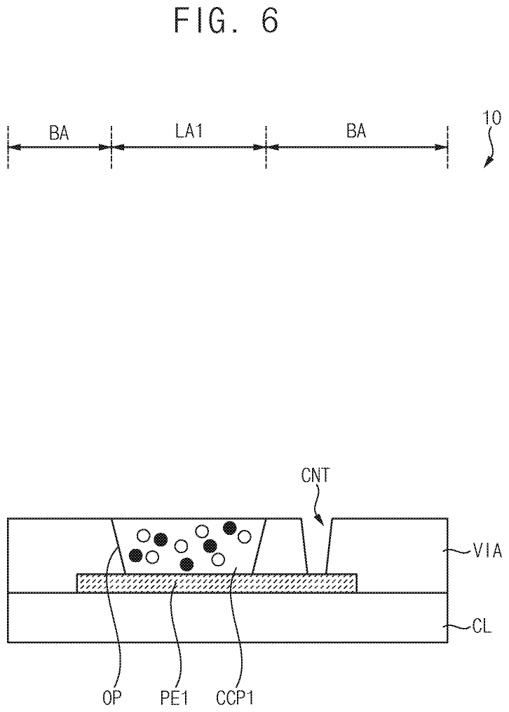

Referring to FIGS. 6, 7, and 8, the first color conversion pattern CCP1 may be formed on the first pixel electrode PE1. For example, the first color conversion pattern CCP1 may be formed in the opening OP of the via insulating layer VIA and may overlap the first light emitting area LA1.

The opening OP may accommodate an ink composition in the process of forming the first color conversion pattern CCP1. The ink composition may be a material forming the first color conversion pattern CCP1. For example, the first color conversion pattern CCP1 may be formed by repeatedly dropping the ink composition into the opening OP using an inkjet device and curing the ink composition. The via insulating layer VIA may prevent or reduce overflow of the ink composition to the outside of the opening OP.

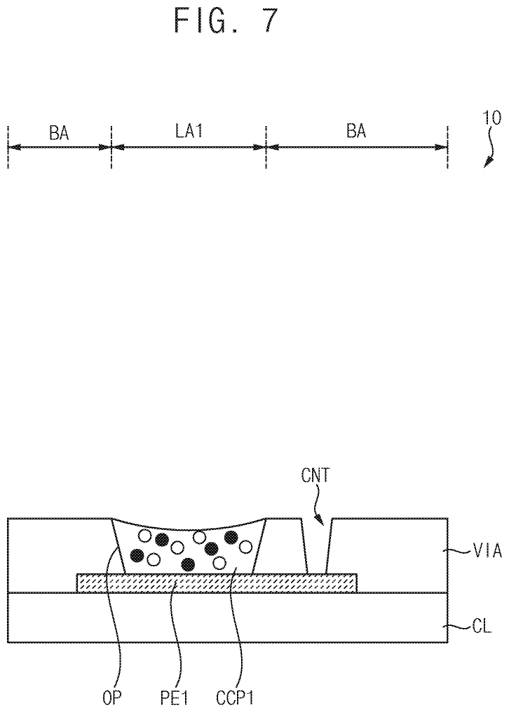

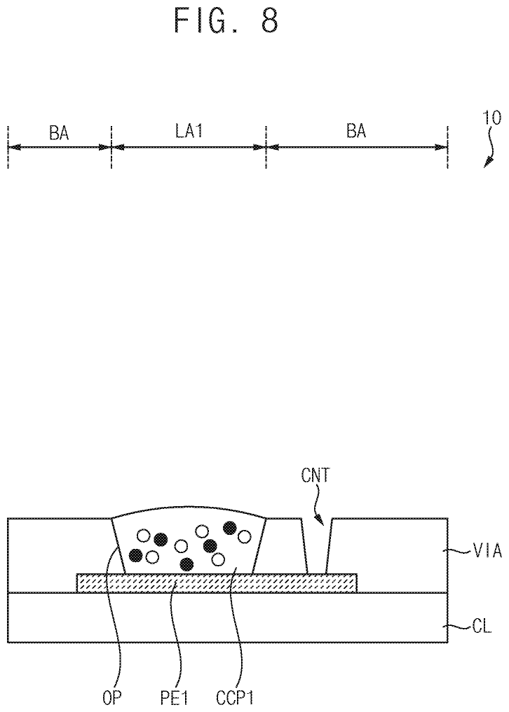

In an embodiment, as the first color conversion pattern CCP1 is formed of the ink composition, an upper surface of the first color conversion pattern CCP1 may have a concave cross-sectional shape (see FIG. 7). In another embodiment, the upper surface of the first color conversion pattern CCP1 may have a convex cross-sectional shape (see FIG. 8).

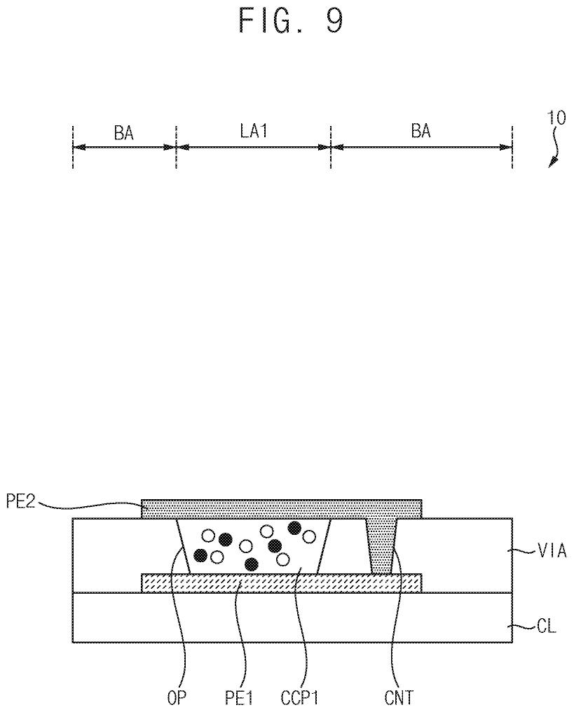

Referring to FIGS. 9, 10, and 11, the second pixel electrode PE2 may be formed on the via insulating layer VIA. The second pixel electrode PE2 may cover the entire upper surface of the first color conversion pattern CCP1 and may overlap the first emitting area LA1. The second pixel electrode PE2 may come into contact (e.g., physical contact) with the first pixel electrode PE1 through the contact hole CNT formed by removing a portion of the via insulating layer VIA. In an embodiment, the second pixel electrode PE2 may have a single-layer structure. For example, the second pixel electrode PE2 may include ITO.

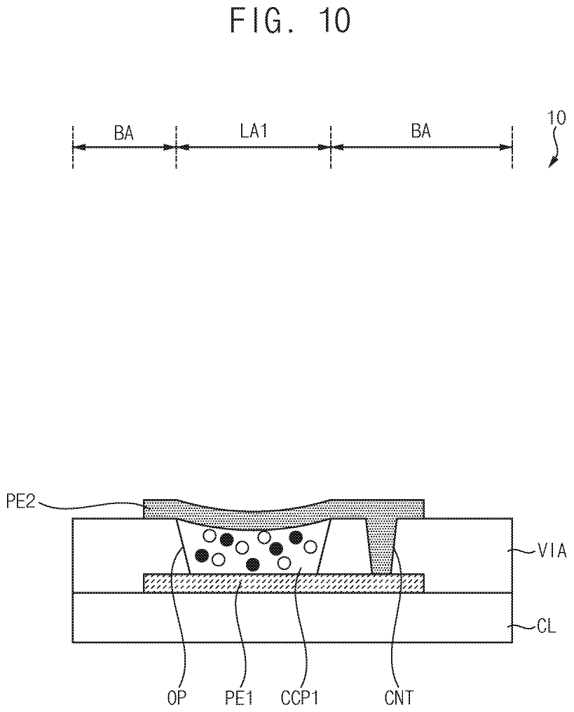

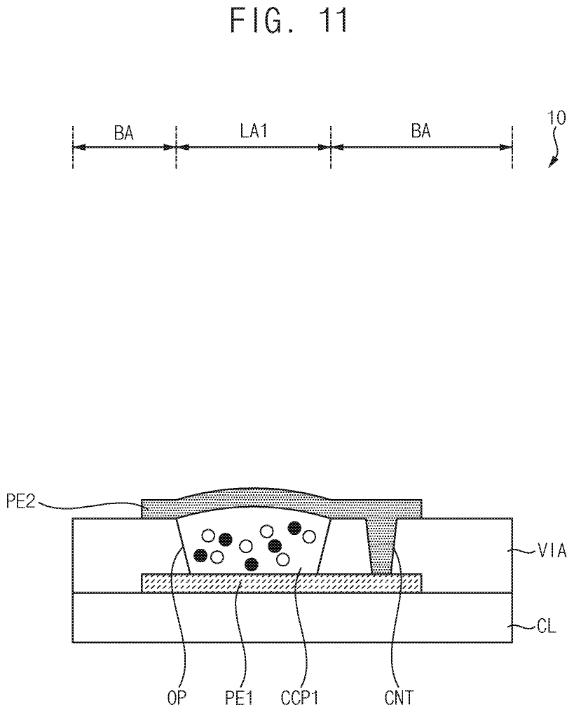

The second pixel electrode PE2 may be formed along the profile of the upper surface of the first color conversion pattern CCP1. For example, the upper surface of the second pixel electrode PE2 overlapping the upper surface of the first color conversion pattern CCP1 may have the same cross-sectional shape as the upper surface of the first color conversion pattern CCP1. In an embodiment, when the upper surface of the first color conversion pattern CCP1 has a concave cross-sectional shape, the upper surface of the second pixel electrode PE2 overlapping the upper surface of the first color conversion pattern CCP1 may have a concave cross-sectional shape (see FIG. 10). In another embodiment, when the upper surface of the first color conversion pattern CCP1 has a convex cross-sectional shape, the upper surface of the second pixel electrode PE2 overlapping the upper surface of the first color conversion pattern CCP1 may have a convex cross-sectional shape (see FIG. 11).

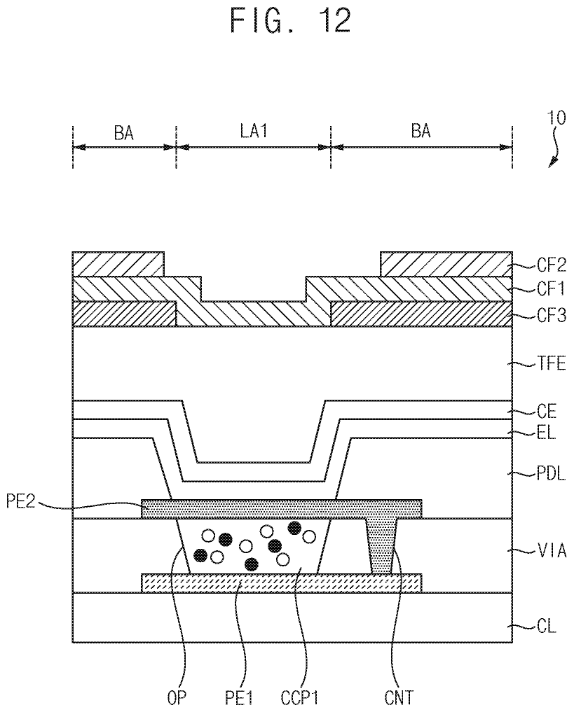

Referring to FIG. 12, the pixel defining layer PDL may be formed on the via insulating layer VIA. The opening that exposes at least a portion of an upper surface of the second pixel electrode PE2 may be formed in the pixel defining layer PDL. The opening may overlap the first emitting area LA1.

The light emitting layer EL may be entirely formed on the pixel defining layer PDL. For example, the light emitting layer EL may be entirely formed in the first light emitting area LA1 and the light blocking area BA. For example, the light emitting layer EL may come into contact (e.g., physical contact) with the second pixel electrode PE2 in the opening of the pixel defining layer PDL.

The common electrode CE may be formed on the light emitting layer EL. The common electrode CE may be entirely formed in the first emitting area LA1 and the light blocking area BA.

The thin film encapsulation layer TFE may be formed on the common electrode CE. The thin film encapsulation layer TFE may be entirely formed in the first light emitting area LA1 and the light blocking area BA.

The color filter layer CFL may be formed on the thin film encapsulation layer TFE. The color filter layer CFL may include the first color filter CF1, the second color filter CF2, and the third color filter CF3. The first color filter CF1 may be formed to partially overlap the first emitting area LA1 and the first color conversion pattern CCP1.

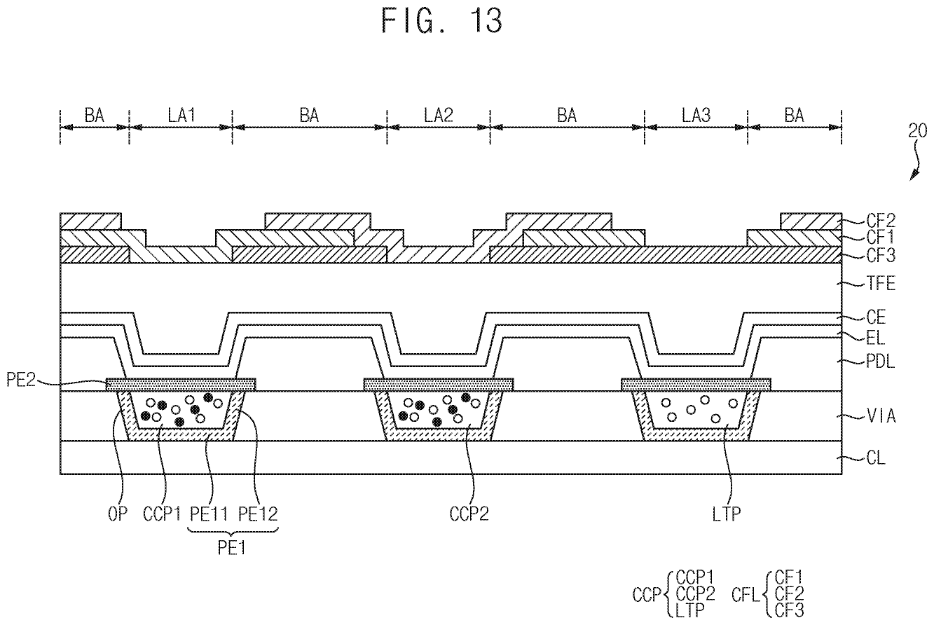

FIG. 13 is a cross-sectional view illustrating a display device according to another embodiment of the present disclosure.

Referring to FIG. 13, a display device 20 according to another embodiment of the present disclosure may include a circuit layer CL, a via insulating layer VIA, a first pixel electrode PE1, a color conversion pattern CCP, a second pixel electrode PE2, a pixel defining layer PDL, a light emitting layer EL, a common electrode CE, a thin film encapsulation layer TFE, and a color filter layer CFL.

Hereinafter, the description which is redundant to the description for the display device 10 described with reference to FIG. 2 may not be repeated or may be simplified.

The via insulating layer VIA may be on the circuit layer CL. In an embodiment, an opening OP that exposes at least a portion of an upper surface of the circuit layer CL may be defined in the via insulating layer VIA. The opening OP may overlap each of first, second, and third light emitting areas LA1, LA2, and LA3.

The first pixel electrode PE1 may be on the circuit layer CL. For example, the first pixel electrode PE1 may be in the opening OP of the via insulating layer VIA.

In an embodiment, the first pixel electrode PE1 may include a first portion PE11 and a second portion PE12. For example, the first portion PE11 may be under the color conversion pattern CCP. The second portion PE12 may extend from the side surface of the first portion PE11 to surround the side surface of the color conversion pattern CCP.

The second pixel electrode PE2 may directly come into contact (e.g., physical contact) with the second portion PE12 of the first pixel electrode PE1. Thus, the second pixel electrode PE2 may be connected to the first pixel electrode PE1 through the second portion PE12.

In the display device 20 according to another embodiment of the present disclosure, because the first pixel electrode PE1 includes the second portion PE12 extending to surround the side surface of the color conversion pattern CCP, the light scattered by the scattering particles included in the color conversion pattern CCP may be subject to specular reflection, thereby increasing the light emitting efficiency. Therefore, the display quality of the display device 20 may be improved.

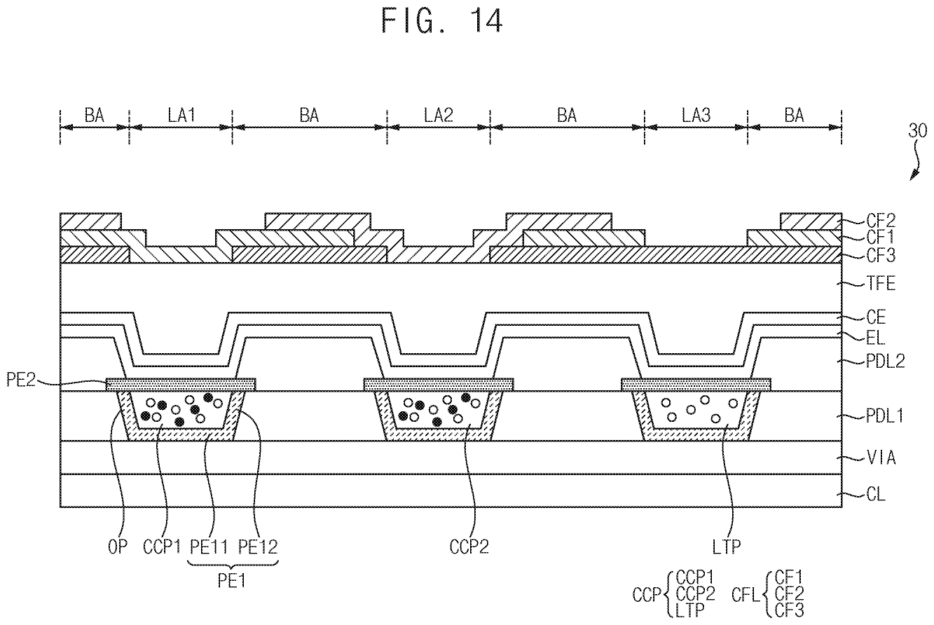

FIG. 14 is a cross-sectional view illustrating a display device according to still another embodiment of the present disclosure.

Referring to FIG. 14, a display device 30 according to still another embodiment of the present disclosure may include a circuit layer CL, a via insulating layer VIA, a first pixel defining layer PDL1, a first pixel electrode PE1, a color conversion pattern CCP, a second pixel electrode PE2, a second pixel defining layer PDL2, a light emitting layer EL, a common electrode CE, a thin film encapsulation layer TFE, and a color filter layer CFL.

Hereinafter, the description which is redundant to the description for the display device 20 described with reference to FIG. 13 may not be repeated or may be simplified.

The via insulating layer VIA may be on the circuit layer CL.

The first pixel defining layer PDL1 may be on the via insulating layer VIA. In an embodiment, an opening OP that exposes at least a portion of an upper surface of the via insulating layer VIA may be defined in the first pixel defining layer PDL1. The opening OP may overlap each of the first, second, and third light emitting areas LA1, LA2, and LA3.

The first pixel defining layer PDL1 may include an organic insulating material (e.g., an organic electrically insulating material). Examples of organic insulating materials that may be used as the first pixel defining layer PDL1 may include photoresist, polyacrylic resin, polyimide resin, acrylic resin, and the like. These materials may be used alone or in combination with each other.

The first pixel electrode PE1 may be on the via insulating layer VIA. For example, the first pixel electrode PE1 may be in the opening OP of the first pixel defining layer PDL1.

In an embodiment, the first pixel electrode PE1 may include a first portion PE11 and a second portion PE12. For example, the first portion PE11 may be under the color conversion pattern CCP. The second portion PE12 may extend from the side surface of the first portion PE11 to surround the side surface of the color conversion pattern CCP.

The color conversion pattern CCP may be on the first pixel electrode PE1. For example, the color conversion pattern CCP may be in the opening OP of the first pixel defining layer PDL1.

The second pixel electrode PE2 may be on the first pixel defining layer PDL1 and the color conversion pattern CCP. The second pixel electrode PE2 may cover the entire upper surface of the color conversion pattern CCP. The second pixel electrode PE2 may directly come into contact (e.g., physical contact) with the second portion PE12 of the first pixel electrode PE1. Accordingly, the second pixel electrode PE2 may be connected to the first pixel electrode PE1 through the second portion PE12.

The second pixel defining layer PDL2 may be on the first pixel defining layer PDL1. In an embodiment, an opening that exposes at least a portion of an upper surface of the second pixel electrode PE2 may be defined in the second pixel defining layer PDL2. The opening may overlap each of the first, second, and third light emitting areas LA1, LA2, and LA3. The second pixel defining layer PDL2 may include an organic insulating material (e.g., an organic electrically insulating material). Examples of organic insulating materials that may be used as the second pixel defining layer PDL2 may include photoresist, polyacrylic resin, polyimide resin, acrylic resin, and the like. These materials may be used alone or in combination with each other.

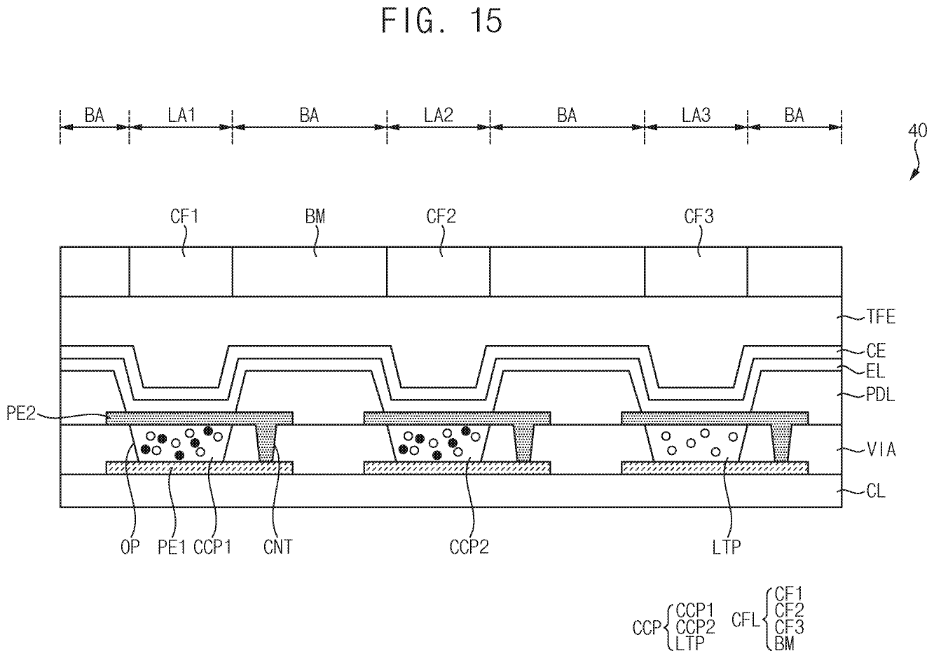

FIG. 15 is a cross-sectional view illustrating a display device according to still another embodiment of the present disclosure.

Referring to FIG. 15, the display device 40 according to still another embodiment of the present disclosure may include a circuit layer CL, a first pixel electrode PE1, a color conversion pattern CCP, a via insulating layer VIA, a second pixel electrode PE2, a pixel defining layer PDL, a light emitting layer EL, a common electrode CE, a thin film encapsulation layer TFE, and a color filter layer CFL.

Hereinafter, the description which is redundant to the description for the display device 10 described with reference to FIG. 2 may not be repeated or may be simplified.

The color filter layer CFL may be on the common electrode CE. The color filter layer CFL may include a light blocking portion BM and first, second, and third color filters CF1, CF2, and CF3.

The first color filter CF1 may overlap the first color conversion pattern CCP1, the second color filter CF2 may overlap the second color conversion pattern CCP2, and the third color filter CF3 may overlap the light transmission pattern LTP. For example, the first color filter CF1 may transmit red light, the second color filter CF2 may transmit green light, and the third color filter CF3 may transmit blue light, but the present disclosure is not limited thereto.

The light blocking portion BM may be a black matrix. The light blocking portion BM may include an organic light blocking material including a black pigment and/or a black dye and/or an inorganic light blocking material. For example, the light blocking portion BM may prevent or reduce light leakage and prevent or reduce mixing of lights of different colors emitted from the color conversion pattern CCP with each other. In addition, the light blocking portion BM may identify boundaries between first, second, and third color filters CF1, CF2, and CF3 adjacent to each other.

The present disclosure can be applied to various suitable display devices. For example, the present disclosure is applicable to various suitable display devices such as display devices for vehicles, ships and aircraft, portable communication devices, display devices for exhibition and/or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the spirit and scope of the present disclosure. Accordingly, all such modifications are intended to be included within the scope of the present disclosure as defined in the claims, and equivalents thereof. Therefore, it is to be understood that the foregoing is illustrative of various embodiments and is not to be construed as limited to the embodiments disclosed, and that modifications to the disclosed embodiments, as well as other embodiments, are intended to be included within the scope of the appended claims, and equivalents thereof.

What is claimed is:

1. A display device comprising:
a substrate;
a color conversion pattern on the substrate and comprising scattering particles;
a first pixel electrode under the color conversion pattern and that extends to surround a side surface of the color conversion pattern;
a second pixel electrode on the color conversion pattern and connected to the first pixel electrode; and
a light emitting layer on the second pixel electrode.

2. The display device of claim 1, wherein the first pixel electrode comprises a first portion under the color conversion pattern and a second portion that extends from a side surface of the first portion to surround the side surface of the color conversion pattern, and
the second pixel electrode directly comes into contact with the second portion of the first pixel electrode.

3. The display device of claim 1, further comprising a via insulating layer on the substrate and that defines an opening overlapping the first pixel electrode,
wherein the first pixel electrode and the color conversion pattern are in the opening.

4. The display device of claim 3, wherein the second pixel electrode is on the via insulating layer.

5. The display device of claim 4, further comprising a pixel defining layer on the via insulating layer to expose at least a portion of the second pixel electrode.

6. The display device of claim 1, further comprising:
a via insulating layer on the substrate; and
a first pixel defining layer on the via insulating layer and that defines an opening that exposes a portion of an upper surface of the via insulating layer,
wherein the first pixel electrode and the color conversion pattern are in the opening.

7. The display device of claim 6, wherein the second pixel electrode is on the first pixel defining layer.

8. The display device of claim 7, further comprising a second pixel defining layer on the first pixel defining layer to expose at least a portion of the second pixel electrode.

9. The display device of claim 1, wherein the first pixel electrode has a multilayer structure, and the second pixel electrode has a single-layer structure.

10. The display device of claim 9, wherein the first pixel electrode comprises ITO/Ag/ITO, and the second pixel electrode comprises ITO.

11. The display device of claim 1, wherein an upper surface of the color conversion pattern has a concave cross-sectional shape or a convex cross-sectional shape.

12. The display device of claim 11, wherein the second pixel electrode is along a profile of the upper surface of the color conversion pattern.

13. The display device of claim 1, further comprising a color filter layer on the light emitting layer and comprising a first color filter, a second color filter, and a third color filter.

14. A display device comprising:
a substrate;
a first pixel electrode on the substrate and having a multilayer structure;
a via insulating layer on the substrate and that defines an opening that exposes a portion of an upper surface of the first pixel electrode;
a color conversion pattern in the opening and comprising scattering particles;
a second pixel electrode on the via insulating layer, connected to the first pixel electrode via a contact hole formed through the via insulating layer, and having a single-layer structure; and
a light emitting layer on the second pixel electrode.

15. The display device of claim 14, wherein the first pixel electrode comprises ITO/Ag/ITO, and the second pixel electrode comprises ITO.

16. The display device of claim 14, further comprising a pixel defining layer on the via insulating layer to expose at least a portion of the second pixel electrode.

17. The display device of claim 14, wherein the via insulating layer comprises a high refractive index material.

18. The display device of claim 17, wherein the via insulating layer has a refractive index of 1.6 or more.

19. The display device of claim 14, wherein an upper surface of the color conversion pattern has a concave cross-sectional shape or a convex cross-sectional shape.

20. The display device of claim 19, wherein the second pixel electrode is along a profile of the upper surface of the color conversion pattern.
